(19) United States
(12) Patent Application Publication
(10) Pub. No.: US 2008/0179520 A1
(43) Pub. Date: Jul. 31, 2008

(54) Direct-view focal plane array

(75) Inventors: Christopher Lee Kauffman, Lake Zurich, IL (US); Sung-Shik Yoo, Palatine, IL (US)

Correspondence Address: BRUCE B. BRUNDA;STETINA BRUNDA GARRED 7 BRUCKER, 75 ENTERPRISE, SUITE 250, ALISO VIEJO, CA, 92656, US

(73) Assignee: Northrop Grumman Corporation

(21) Appl. No.: 11/699,839

(22) Filed: Jan. 30, 2007

(51) Int. Cl. H01L 25/00; G01J 5/00

(52) U.S. Cl. 250/332

(57) ABSTRACT

A direct-view focal plane array (FPA) having a detector layer, an amplification layer, a non-uniformity correction layer and a display layer. A direct path from the detector to the display element in each pixel may be established via a configurable digitally set analog circuit that controls gain and level for non-uniformity correction. The detector layer is operative to detect an infrared image with a raw image pixel response x and convert the infrared image into an electrical signal. The electrical signal is then fed into the amplification layer for amplification and the non-uniformity layer for offset and gain correction. An offset correction coefficient b and a gain correction coefficient m are inputted to the non-uniformity layer, to transform the raw image pixel response x into a corrected pixel response y, which prevents the true scene content from bein masked by the fixed pattern.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

The present invention relates in general to a focal plane array, and in more particular, to a direct-view focal plane array.

Several goggle technologies have been developed to convert light or image in various infrared ranges into visible images, so as to allow the observers to see or detect images or objects in various ambient conditions. For example, night vision goggle technologies have been developed that allow imaging nighttime low light level scenes to a display for easy viewing by the human eye. Existing light is amplified and displayed on a phosphor screen without the need for high power raster scanning of a detector array or of the display. This technology is also known as image intensifying (I2) goggles. An important aspect of this technology is its light weight and low power dissipation allowing many hours of operation using only a couple commercial off-the-shelf batteries. The limitation of this technology is its inability to perform thermal imaging while maintaining the same power and weight characteristics (i.e., low power and light weight) needed by a goggle device. For example, in low light conditions (e.g., cloud cover and no ambient light), I2 goggles will not work. To make I2 goggles work in low light conditions, the wavelength response of the I2 goggle must be extended via a photocathode so that it can view thermal imagery. However, the photocathode would have to be cooled to reduce thermal generated carriers. The reason is that photocathodes used in I2 goggles are ambient temperature devices and do not have provisions for temperature control. Unfortunately, cooling of the photocathode would lead to high power dissipation and larger size and weight.

Prior art thermal imagers consume too much energy for use in a goggle. Thermal imaging systems create images of heat patterns and are useful even when there is no ambient light. There are many types of detectors that are used to detect thermal infrared light that occurs with greater than approximately 3.0 microns in wavelength such as solid state photovoltaic or photoconductive infrared detectors. Unfortunately, these detectors require cooling systems such as cryogenic closed cycle types and thermoelectric types which all require too much power to be feasible for use in a goggle. Uncooled bolometer type detectors do not require any cooling nor thermal stabilization systems. Unfortunately, even these types of detectors when coupled to focal plane array readout electronics, digitizing electronics, drive electronics, digital signal processing electronics, and display electronics require too much power to be feasible for use in a goggle. State of the art in low power camera design has produced an imaging module that only requires approximately 1 W of electrical power to operate, and this does not include the display. Unfortunately, even these imaging modules would use up the batteries for night vision goggles in less than one hour. Excessive power requirements of the systems discussed above require special batteries that increase the cost, size and weight of the systems.

In summary, the prior art focal plane array based systems have the desired functionality, but require too much power and are too large for man-portable goggle type applications. Therefore, there is a substantial need in the art to provide a focal plane array based system that provides the desired functionality, packaged in a small size and operates at low power.

### BRIEF SUMMARY

A direct-view focal plane array operative to detect infrared and convert the infrared light into a visible image is provided. With the direct-view focal plane array, an infrared object or spatial image can be viewed directly by human eyes or a conventional visible focal plane array. The direct-view focal plane array as provided eliminates the requirement of multiplexing and de-multiplexing processes, digitization, high-speed digital data manipulation and operations, and signal conditioning on a continuous basis. By the direct-view focal plane array, a direct path from the detector to the display element is established via a configurable digitally set analog circuit that controls gain and level for non-uniformity correction (NUC). Configurable pixels, switchable to be used for symbology (by way of example and not limitation, text on the display) or for displaying the detector signal, are formed. The ability to add functionality by adding layers allowing additional capability to multiplex images on demand for capture and transmission of images of interest is enabled. The direct-view focal plane further allows for image processing functions in the layers such as interpolation where one detector influences many higher resolution display pixels. The enabling technology may be characterized as the ability to form circuitry on layers that can be stacked while having interconnection at the pixel level that results in a vertically integrated circuit. By way of example and not limitation, there may be a detector at the input of this vertically integrated circuit, and a display element at the output of the vertically integrated circuit thereby forming one pixel. The vertically integrated pixels may be arranged in a two dimensional mosaic array organized in a rectilinear fashion, or some other pattern such as an interleaved or honeycomb pattern that determines an active electro-optical focal plane on both sides of the array. The individual pixels functions may be controlled using circuitry located at the periphery of this active pixellated region.

The direct-view focal plane array may comprise a detector layer, an amplification layer, a non-uniformity correction layer and a display layer. A layer is defined in this text in terms of functionality and also in terms of physical circuitry. One or more layers of functionality may reside in one layer, or level, of physical circuitry. The detector layer is operative to detect an infrared image with a raw image pixel response x and convert the infrared image into an electrical signal. The electrical signal is then fed into the amplification layer for pre-amplification to enable detector noise limited performance and the non-uniformity layer for offset and gain correction. In the case where a simple two-point non-uniformity correction scheme is used, an offset correction coefficient b and a gain correction coefficient m are input to the non-uniformity layer, such that the raw image pixel response x can be transformed into a corrected pixel response y by the relationship of y=mx+b. Thereby, the true scene content in the image captured by the detector layer will not be masked by the fixed pattern while being displayed by the display layer. Other methods of fixed pattern noise suppression known in the art or developed in the future may also be implemented as well.

The direct-view focal plane array may include a two-dimensional array of pixels, and each pixel may include a detector unit, an amplification circuit, a gain-correction circuit, and a display unit. The detector unit may be operative to detect an infrared optical signal with a raw image pixel response x and convert the infrared signal into an electrical signal. The amplification circuitry may be operative to amplify the electrical signal and to offset the raw image pixel response x by an offset correction coefficient b. The gain correction circuitry is operative to provide a gain correction coefficient m to the raw image pixel response x. The display unit may be operative to convert the amplified and corrected electrical signal into a visible signal with a corrected pixel response y, wherein y=mx+b. Preferably, both the offset and gain correction values m and b are analog to reduce the circuit complexity to perform non-uniformity correction. Digital signals are also contemplated. The amplification circuitry in the preferred embodiment may comprise a digital-to-analog converter to convert a predetermined digital offset correction value into the analog offset correction coefficient b, and the gain correction circuitry comprises a digital-to-analog converter to convert a predetermined digital gain correction value into the analog gain correction coefficient m. The display unit includes a light-emitting device such as an organic light-emitting diode (OLED) unit or a field-emission display (FED) unit. The focal plane array may further comprise a buffer to temporarily store the electrical signal before being fed to the amplification circuitry. The amplification circuitry and the gain correction circuitry can be integrated on a single or multiple layers. In addition, the detector unit, the amplification circuitry, the gain correction circuitry, and the display unit may be in electrical communication with each other and integrated by vertical integrated sensor array technology.

It is contemplated to multiplex small groups of detectors with small groups of corresponding display elements to reduce the number of interconnects between each layer. For example, the FPA may be organized into smaller arrays, such as 2×2 subarrays, (that may be multiplexed at a relatively low frequency as compared to a conventional FPA, but high enough that the transitions between pixels is transparent to the human eye) through one interconnect for each subarray in the FPA, to the corresponding 2×2 subarray of display elements. In this way, only one interconnect is required for the subarray as compared to four interconnects in this case. Multiplexing the small subarrays will add some complexity and power dissipation to the circuitry.

The focal plane array can be used in a goggle to provide direct view for a user or an observer under various ambient conditions. The goggle includes an objective optic for focusing infrared light onto the focal plane array. The focal plane array then converts the infrared optical signal into a visible optical signal for the user to observe. There may also be an optical element on the visible side of the focal plane array to enable easier viewing by the observer. The direct view focal plane array may also be used with a normal visible camcorder or digital camera to view a scene in the infrared in conjunction with a re-imaging optics chain with the direct view FPA at the intermediate focal plane of the optical system.

The direct-view focal plane array focal plane array can be operated with a very low power and used as an infrared, or thermal, goggle, a LLL (low light level) SWIR (shortwave infrared) goggle, or a LLL (low light level) visible goggle, depending on the specific type of detector array as selected. The direct-view focal plane array may be in the form of a multi-layer semiconductor circuit. On one side of the multi-layer semiconductor circuit may be an array of detectors, and on the other side may be an array of low power display elements.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a diagram showing the functions normally found in a conventional time division multiplexed FPA, with the functions outlined in the dashed line of the functions not required in the Direct View FPA;

FIG. 2 shows the multi-layer structure of an exemplary direct-view focal plane array;

FIG. 3 shows an exemplary arrangement of pixels of the direct-view focal plane array as illustrated in FIG. 2;

FIG. 4 shows the circuit diagram of each pixel of the direct-view focal plane array as shown in FIG. 2; and

FIG. 5 shows the realization of direct view provided by the focal plane array.

### DETAILED DESCRIPTION

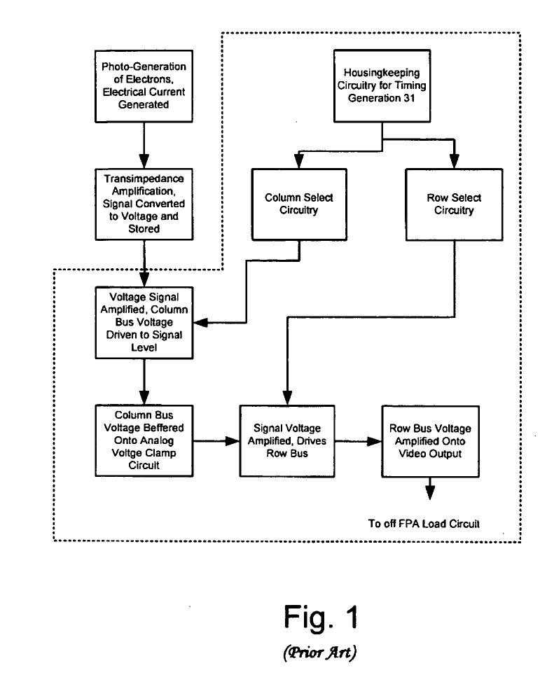

As discussed above, most of the currently available prior art focal plane array systems that have the desired functionality require too much power for man-portable goggle type applications. The functions that consume significant power are listed in Table I and outlined for the FPA alone in the functional signal flow diagram as shown in FIG. 1. As shown, for a typical conventional time-division multiplexed FPA based imaging system, when an electrical current is generated by the photo-generated electrons, trans-impedance amplification is performed and the signal carried by the electrical current is converted into a voltage signal and temporarily stored. According to the housekeeping circuit, high-speed switching and high-bandwidth amplification are continuously performed on the voltage signal for every pixel of every frame to provide a video output, and many functions are performed off of the focal plane array after the output of the pixels has been digitized using high power digital signal processors. Therefore, although the system of signal processing as illustrated allows flexibility in design, it is extremely inefficient during operation.

TABLE I

| On Focal Plane Array | Off Focal Plane Array |
|---|---|
| Detector Bias | Video Output Load |
| Detector Interface Amplifier | Video Buffer, Pre-Amp |
| Time Division Multiplexing - | ASIC/FPGA and Digital Support |
| Column Select (Slow Speed) | Circuitry |
| Circuitry | Power Regulation and Distribution |
| Analog Column Amplification | Digital Drive Circuitry |
| Column Buffer Amplifier | Display Drive Circuitry - |
| Row Select (High Speed) Circuitry | Demultiplexing, Video |
| Housekeeping Functions | Amplification, Bias |
| For Timing | |
| Video Output Amplifier | |

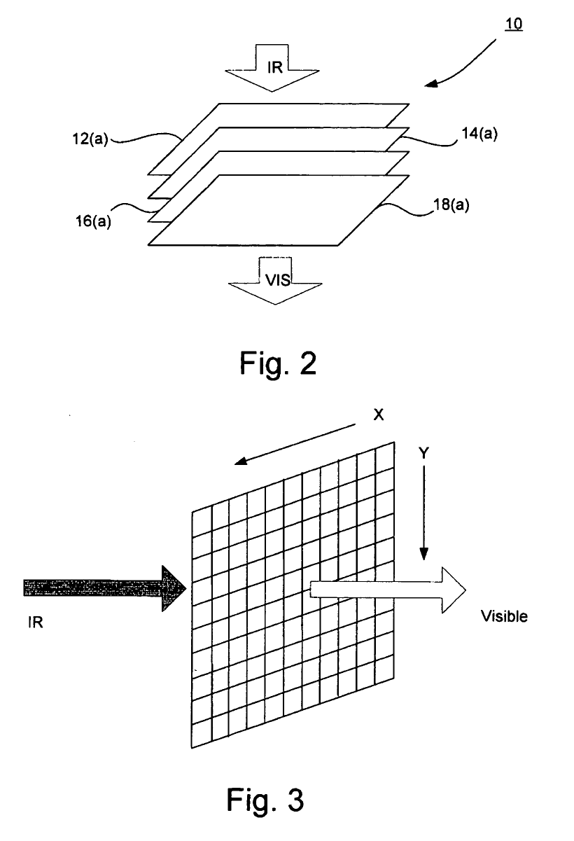

To resolve the power consumption issue, the continuous operation of the circuitry that provides the high-speed switching and the high-bandwidth amplification outlined in FIG. 1 is eliminated in the embodiment as shown in FIGS. 2-4. As shown in FIG. 2, the direct-view focal plane array 10 includes a detecting layer 12 at one side and a display layer 18 at the opposite side thereof. The detecting layer 12 includes an array of detectors 12a operative to detect infrared light, and the display layer 18 includes an array of display elements 18a operative to display the image or light detected by the detecting layer 12 in the visible wavelength range. The detecting layer 12 and the display layer 18 are connected to each other through one or more circuit layers, and the VISA (vertically integrated sensor array) technology allows the layer-to-layer connection for each pixel of the focal plane array 10. Each of the circuit layers sandwiched between the detecting layers 12 may be designed with one or more specific functions, such as amplification, non-uniformity correction, and display adjustment. In this embodiment, two circuit layers, including the amplification layer 14 and the uniformity correction layer 16 are formed and stacked between the detecting layer 12 and the display layer 18.

The direct-view focal plane array 10 as shown in FIG. 2 includes an array of pixels arranged along the X-axis and Y-axis to provide a two-dimensional imaging. The array of pixels and conversion of light are illustrated in FIG. 3. As shown, each of the pixels is operative to detect an optical infrared or visible photon signal and convert this signal into a visible image directly viewable by the user. Depending on the specific requirement, the focal plane array may incorporate various detectors so that it may be used as a thermal goggle, a LLL SWIR goggle, or a LLL visible goggle.

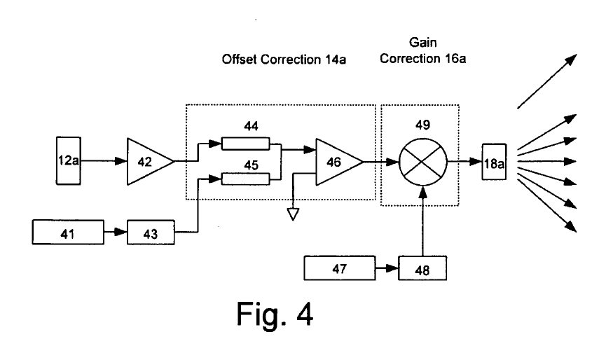

The circuit for each pixel as shown in FIGS. 2 and 3 is illustrated in FIG. 4. As shown, each of the pixels may include an optical infrared or visible photon detector unit 12a for absorbing the optical infrared or visible photon image and a display unit 18a for displaying the image in the visible wavelength range. Again, depending on the specific requirement or application, the optical infrared or visible photon detector unit 12a may be operative to detect images at various ranges of light such as visible, NIR (near infrared), SWIR, MWIR (mid wave infrared) or LWIR (long wave infrared) depending on the type of detector chosen. To minimize the volume of the focal plane array 10, the display unit 18a may be selected from a flat panel display such as organic light-emitting diode (OLED), field-emission display (FED), or other visible display device. Similar to the functions as shown in FIG. 2, once an image is detected by the detector unit 12a, an electrical current is photo-generated and converted into a voltage signal in amplifier 42, also shown as a functional amplification layer 14. The voltage signal is then fed to uniformity correction circuit 16, and then displayed by the display unit 18a. As shown in FIG. 4, each of the pixels comprises a unit 14a of the amplification 14 and a unit 16a of the uniformity correction circuit 16. The amplification unit 14a includes an amplifier 42 of which, in this embodiment, converts the detector signal into a voltage.

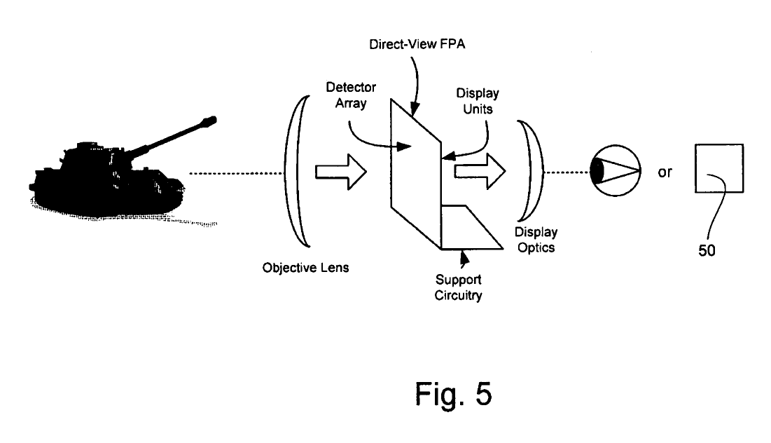

The output of the amplifier 42 is input to unit 14a. The non-uniformity correction unit may comprise offset correction 14a and gain correction 16a. The non uniformity correction unit may comprise an offset stage, here shown as a summing amplifier 46 with the negative input connected with two resistors 44 and 45, where the resistor 44 is connected to the buffer 42 allowing the voltage signal to be input to the offset unit 16a, and the resistor 45 is fed with an analog offset value converted from a predetermined digital offset value converted by a digital-to-analog converter 43. The positive input of the amplifier 46 is grounded in this embodiment and a multiplier 49 is used for gain correction. A predetermined digital gain value is converted to an analog gain value by a digital-to-analog converter 48 and input to the multiplier 49 allowing the gain to be corrected according to the digital gain value. The output of the multiplier 49, that is, the non-uniformity correction circuit unit 16a is then connected to the display unit 18a for displaying the image captured by the detector unit 12a in the visible wavelength range, such that the observer or user can obtain a direct view of the infrared image as shown in FIG. 5. Additionally or alternatively, a video recorder or a still image recorder 50 may be placed in front of the display unit 18 such that the video recorder or still image recorder 50 can obtain a direct view of the infrared image (see FIG. 5). The video recorder or still image recorder 50 may be a visible camera (e.g., camcorder, digital photographic camera, or visible film camera).

The offset and gain corrections as described above are the coefficients used for non-uniformity correction. As understood, there is very low contrast in the infrared wavelength range or at low light levels in the visible wavelength range, so that any slight difference in the responses between pixels to the same input stimulus will cause a fixed pattern to appear in the image that masks the true scene content. This is called fixed pattern noise. The response curve of each pixel is modeled as a linear function of output pixel response over the input optical power incident on the pixel. By adjusting the offset level and the gain level for each pixel, all of the apparent pixel responses can be made to look exactly alike. In the prior art, the output of a focal plane array is directly applied to a digitizer and all of the pixel responses are fed to a digital signal processor with all of the non-uniformities, and the corrected image is calculated digitally using stored calibration coefficients for each pixel. These operations must be performed on every pixel for every frame. In contrast, in the embodiment as shown in FIG. 4, the two-point correction is merely a linear equation y=mx+b. Other methods of fixed pattern noise suppression known in the art or developed in the future may be implemented as well. This is called as a two-point correction because two calibration points are collected on the raw pixel response to describe the raw linear transfer function thereof, and two correction coefficients are generated. In the linear equation, x is the raw pixel response, b is the offset correction, m is the gain correction coefficient, and y is the corrected pixel response. These operations may be performed in analog in the pixel circuitry using digitally controlled voltage to control the gain and offset levels. As the operating temperature changes, new coefficients would have to be loaded because the detector transfer function changes as the operation temperature thereof changes. This can be accomplished at a relatively low speed because the temperature change is not likely to not occur very quickly. This saves power effectively because the digital “housekeeping” is only required at startup and every so often when the coefficients need to be updated or when the user wants to save an image. There is no continuous framing operation as in conventional prior art systems, so the direct view FPA described herein provides a continuous image to the user without time division multiplexing. This makes the system the most efficient way to convert the infrared scene to a visible scene continuously for the human eye to observe, and therefore a goggle utilizing this direct view FPA can operate from battery power for much longer periods of time than a conventional imaging system. As the life cycle cost of this type of goggle system is dominated by batteries, the life cycle cost can be reduced dramatically over a typical video system from the lower power required.

In an aspect of the focal plane array discussed herein, the same may be electrically connected to peripheral circuitry. The peripheral circuitry may be connected to certain pixels for use in symbology such as text, numbers, stop sign, left turn, etc. The peripheral circuitry may be operative to send a high or low voltage based on the symbol to be displayed. By way of example and not limitation, inputs of certain pixels may be connected to a high or low voltage rail instead of the detector.

In an aspect of the focal plane array discussed herein, the same may be optionally be in communication with peripheral circuitry. The peripheral circuitry may receive the information provided by the outputs of the pixels and produce a time-division multiplexed video signal for viewing by another user(s).

The above description is given by way of example, and not limitation. Given the above disclosure, one skilled in the art could devise variations that are within the scope and spirit of the invention disclosed herein. Further, the various features of the embodiments disclosed herein can be used alone, or in varying combinations with each other and are not intended to be limited to the specific combination described herein. Thus, the scope of the claims is not to be limited by the illustrated embodiments.

1. A direct-view focal plane array, comprising:
a detector layer defining a plurality of detector unit subarrays, the detector layer operative to detect an image and generate an image response;
first circuitry layer in electrical communication with the detector layer and operative to receive the image response;
a plurality of electrical vias electrically connected to the first circuitry layer, a one of the plurality of electrical vias in electrical communication with only one of the plurality of detector unit subarray;
a second circuitry layer electrically connected to the plurality of electrical vias and operative to receive the image response through the plurality of electrical vias;
a display layer defining a plurality of pixel subarrays, a one of the plurality of pixel subarray in electrical communication with only one of the plurality of electrical vias, the display layer operative to display the image response into a visible image;
wherein the detector layer, first and second circuitry layers and display layer form a stack.

2. The focal plane array of claim 1, wherein a corrected pixel response and the image response have a relationship of y=mx +b wherein y is a corrected response, m is a responsivity correction coefficient, x is the image response and b is an offset correction coefficient.

3. The focal plane array of claim 1, wherein the detector layer includes a plurality of infrared detector units arranged in a two-dimensional array.

4. The focal plane array of claim 1, further comprising a buffer for temporarily storing the image.

5. The focal plane array of claim 2 wherein the first or second circuitry layers include an amplification circuit to amplify the image and a non-uniformity circuit to perform non-uniformity correction on the image based on an offset correction coefficient b.

6. The focal plane away of claim 5, wherein the amplification circuit includes a summing amplifier having a negative input connected to an output of the detector layer and a positive input connected to ground.

7. The focal plane array of claim 5, wherein the non-uniformity correction circuit comprises at least one digital-to-analog converter for converting a predetermined digital offset value into the analog offset correction coefficient b and a predetermined digital gain value into the analog gain correction coefficient m.

8. The focal plane away of claim 5, wherein the non-uniformity correction circuit is operative to receive and apply new analog offset and gain coefficients b‘ and m‘ when an operating temperature is changed or when the detector response drifts.

9. The focal plane array of claim 1, wherein the display layer includes an array of organic or inorganic light-emitting diode display element or an away of field emission display element.

10. The focal plane array of claim 5 wherein the amplification circuit and the non-uniformity layer reside on one or more physical layers.

11. The focal plane away of claim 1 further comprising a peripheral circuit connected to pixels and operative to form a symbol on the display layer.

12. The focal plane away of claim 1 further comprising a peripheral circuit operative to receive information from outputs of the display layer.

13. A direct-view focal plane array having an array of pixels, each of the pixels comprises:
a detector unit, operative to detect an infrared optical signal with a raw image pixel response and convert the infrared signal into an electrical signal;
an amplification circuit, operative to amplify the electrical signal and to offset the raw image pixel response x by a offset correction coefficient b;
a gain correction circuit, operative to provide a gain correction coefficient m to the raw image pixel response x; and
a display unit, operative to convert the amplified and corrected electrical signal into a visible signal with a corrected pixel response y, wherein y=mx +b;
wherein the detector units is stacked on the display units and connected to the display unit through a single electrical interconnect.

14. The direct focal plane array of claim 13, wherein both the offset and gain correction coefficients m and b for each pixel are analog.

15. The direct focal plane array of claim 14, wherein the amplification circuitry for each pixel comprises a digital-to-analog converter to convert a predetermined digital offset correction value into the analog offset correction coefficient b.

16. The direct focal plane array of claim 14, wherein the gain correction circuit in each pixel comprises a digital-to-analog converter to convert a predetermined digital gain correction value into the analog gain correction coefficient m.

17. The focal plane array of claim 13, wherein the display unit for each pixel includes a light-emitting device.

18. The focal plane array of claim 17, wherein each pixel of the light-emitting device includes an inorganic or organic light-emitting diode unit or a field-emission display unit.

19. The focal plane array of claim 13, further comprising a buffer for temporarily storing the electrical signal before being fed to the amplification circuit.

20. The focal plane array of claim 13, wherein the amplification circuitry and the gain correction circuitry are integrated on a single or multiple layers.

21. The focal plane array of claim 13, wherein the detector unit, the amplification circuit, the gain correction circuit, and the display unit are electrically connected to one another and integrated in each pixel by vertically integrated sensor array technology.

22. A focal plane array based goggle, comprising:
an objective optic;
a focal plane array comprised of a plurality of two dimensional subarrays of pixels for detecting an infrared optical signal traveling through the objective optic and to convert the infrared optical signal into a visible optical signal in each pixel directly, the subarray of pixels comprising:
a two dimensional subarray of detectors operative to convert the infrared optical signal into electrical signals;
a two dimensional subarray of amplifiers, operative to amplify the electrical signals;
a two dimensional subarray of non-uniformity correction circuits operative to perform non-uniformity correction by applying a gain correction coefficient and an offset correction coefficient to the electrical signal in each pixel to normalize pixel response non-uniformities; and
a two dimensional subarray of display elements operative to convert the amplified and corrected electrical signals into a two dimensional visible optical signals wherein the subarray of detectors is stacked on and connected to the corresponding subarray of display elements through a single electrical interconnect; and
display optics disposed adjacent the focal plane array for directing the visible image generated by the focal plane array to an observer.

23. The goggle of claim 22, wherein the focal plane array is formed by vertically integrated sensor technology.

24. The goggle of claim 22, comprising a thermal goggle, a low-light-level short-wavelength infrared goggle, or a low-light-level visible goggle.

25. The goggle of claim 22, wherein the focal plane array includes a plurality of two dimensional subarray of pixels.

26. The goggle of claim 22 wherein the subarray of amplifiers and subarray of non-uniformity correction circuits reside on one or more physical layers.

27. A focal plane array based re-imaging optical system for a video recorder or a still image recorder, comprising:
a focal plane array comprised of a plurality of two dimensional subarray of pixels for detecting an infrared optical signal traveling through an objective optic which passes light and converts the infrared optical signal into a visible optical signal, the subarray of pixels comprising:
a two dimensional subarray of detectors operative to convert the infrared optical signal into electrical signals;
a two dimensional subarray of amplifiers, operative to amplify the electrical signals;
a two dimensional subarray of non-uniformity correction circuits operative to perform non-uniformity correction by applying a gain correction coefficient and an offset correction coefficient to the electrical signal in each pixel to normalize pixel response non-uniformities; and
a two dimensional subarray of display elements operative to convert the amplified and corrected electrical signals into a two dimensional visible optical signal wherein the subarray of detectors is connected to the corresponding subarray of display elements through a single electrical interconnect; and
display optics in communication with the focal plane array; and
a video recorder or a still image recorder directed toward the display optics for directing the visible image generated by the focal plane array to the video recorder or the still image recorder.

28. The focal plane array based re-imaging optical system of claim 27, wherein the focal plane array is formed by vertically integrated sensor technology.

29. The focal plane array based re-imaging optical system of claim 27 wherein the system is a thermal focal plane array based re-imaging optical system, a low-light-level short-wavelength infrared focal plane away based re-imaging optical system, or a low-light-level visible focal plane away based re-imaging optical system.

30. (canceled)

31. The focal plane array based re-imaging optical system of claim 27 wherein the subarray of amplifiers and the subarray of non-uniformity correction circuits reside on one or more physical layers.

32. The focal plane array based re-imaging optical system of claim 27 wherein the video recorder is a visible light camcorder.

33. The focal plane array based re-imaging optical system of claim 27 wherein the still image recorder is a digital camera.

34. The focal plane array based re-imaging optical system of claim 27 wherein the still image recorder is a visible FPA based camera system.
